(19) United States
(12) Patent Application Publication
(10) Pub. No.: US 2008/0272480 A1
(43) Pub. Date: Nov. 6, 2008

(54) Land grid array semiconductor package

(75) Inventors: Chia-Yu Hung, Hsinchu (TW); Chao-Hsiang Leu, Hsinchu (TW); Tseng-Shin Chiu, Hsinchu (TW)

Correspondence Address: TROXELL LAW OFFICE PLLC, SUITE 1404, 5205 LEESBURG PIKE, FALLS CHURCH, VA, 22041, US

(73) Assignee: POWERTCH TECHNOLOGY INC.

(21) Appl. No.: 11/797,637

(22) Filed: May 4, 2007

(51) Int. Cl. H01L 23/49

(52) U.S. Cl. 257/693; 257/E23.024

(57) ABSTRACT

An LGA (Land Grid Array) semiconductor package mainly comprises a substrate, a chip, a soldering layer and a foot stand. The chip is disposed on a top surface of the substrate and is electrically connected to a plurality of metal pads formed on a bottom surface of the substrate. The soldering layer is disposed on the metal pads with a first thickness slightly protruded from the bottom surface of the substrate. Additionally, the foot stand is disposed under the substrate with a second thickness protruded from the bottom surface of the substrate, wherein the second thickness is greater than the first thickness. Therefore, the soldering layer of the LGA semiconductor package is free from scratches and damages during shipping and handling processes. Moreover, the LGA semiconductor package can be surface-mounted to a printed circuit board with pre-applied solder or pre-mounted solder balls to increase the implementations of LGA semiconductor packages.

### FIELD OF THE INVENTION

The present invention relates to a semiconductor package, more particularly, to a LGA (Land Grid Array) semiconductor package.

### BACKGROUND OF THE INVENTION

In a conventional LGA semiconductor package, a plurality of metal pads are disposed in an array at the bottom surface of the package as external electrical terminals contacting with a plurality of metal pins on a circuit board. In order to have good electrical connections, a specific socket with a cover to hold the conventional LGA semiconductor package with the metal pins aligned and contacted the metal pads of the conventional LGA semiconductor package.

Referring to FIG. 1, the conventional LGA semiconductor package 100 mainly comprises a substrate 110 and a chip 120 where the substrate 110 has a top surface 111, a bottom surface 112, and a plurality of metal pads 113 disposed on the bottom surface 112 in an array. The chip 120 is disposed on the top surface 111 of the substrate 110 and is electrically connected to the substrate 110 via a plurality of bumps 140. The LGA semiconductor package 100 further comprises an encapsulant 130, such as underfill materials, formed on the top surface 111 of the substrate 110 to encapsulate the bumps 140. Besides, the LGA semiconductor package 100 further comprises a plurality of passive components 150 disposed on the bottom surface 112 of the substrate 110 and a heat sink 160 disposed on the top surface 111 of the substrate 110. Since sockets with metal pins are the only electrical connections for the conventional LGA semiconductor package 100, therefore, the implementations of LGA semiconductor package 100 are limited. Moreover, during shipping and handling, the metal pads 113 and the passive components 150 located at the bottom surface 112 of the LGA semiconductor package 100 are subjected to scratches and damages.

### SUMMARY OF THE INVENTION

The primary purpose of the present invention is to provide a LGA semiconductor package which can be implemented by SMT (Surface Mount Technology) method in addition to a conventional socket to prevent the metal pads or soldering layers from scratches or damages and to effectively increase the implementations of LGA semiconductor packages.

The secondary purpose of the present invention is to provide a LGA semiconductor package to prevent the scratches of passive components during shipping and handling.

The third purpose of the present invention is to provide a LGA semiconductor package to reduce the cost of forming foot stands under the package.

According to the present invention, a LGA semiconductor package comprises a substrate, a chip, a soldering layer and at least a foot stand. The substrate has a top surface and a bottom surface with-a plurality of metal pads arranged in an array on the bottom surface. The chip is disposed on the top surface of the substrate and is electrically connected to the metal pads. The soldering layer is disposed on the metal pads and has a first thickness slightly protruded from the bottom surface of the substrate. The foot stand is disposed under the substrate and has a second thickness protruded from the bottom surface of the substrate where the second thickness is greater than the first thickness.

### DESCRIPTION OF THE DRAWINGS

FIG. 1 is a cross-sectional view of a conventional LGA semiconductor package.

FIG. 2 is a cross-sectional view of a LGA semiconductor package according to the first embodiment of the present invention.

FIG. 3 is a partial enlarged cross-sectional view of the LGA semiconductor package according to the first embodiment of the present invention.

FIG. 4 is a bottom view of the LGA semiconductor package according to the first embodiment of the present invention.

FIG. 5 is a cross-sectional view of another LGA semiconductor package during shipping and handling according to the second embodiment of the present invention.

FIG. 6 is a bottom view of the LGA semiconductor package according to the second embodiment of the present invention.

FIG. 7 is a cross-sectional view of the LGA semiconductor package during SMT process according to the second embodiment of the present invention.

FIG. 8 is a cross-sectional view of another LGA semiconductor package according to the third embodiment of the present invention.

FIG. 9 is a cross-sectional view of another LGA semiconductor package according to the fourth embodiment of the present invention.

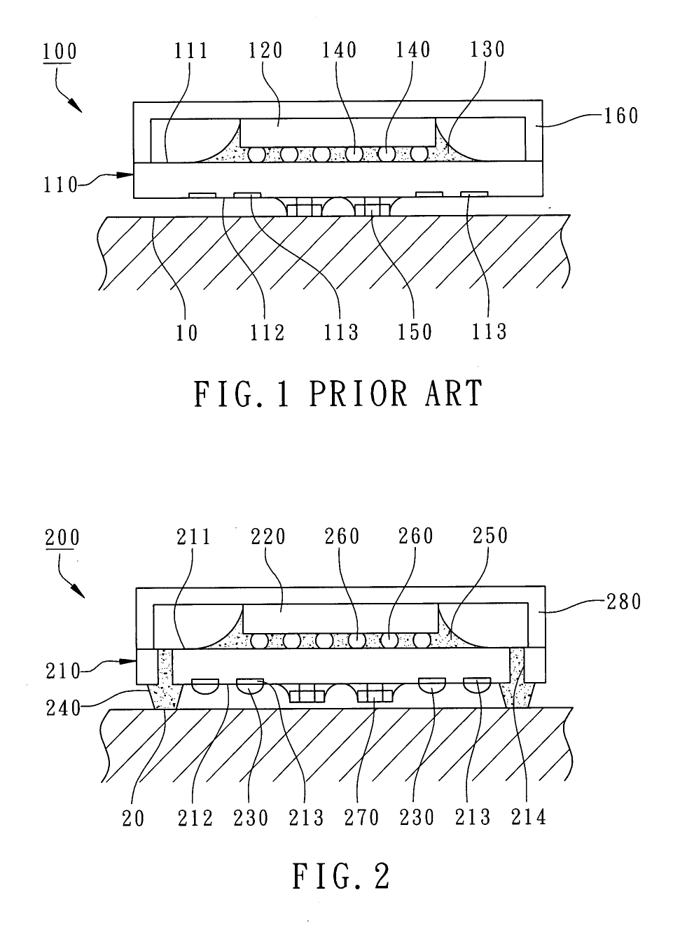

### DETAILED DESCRIPTION OF THE INVENTION

According to the first embodiment of the present invention, a LGA semiconductor package with flip-chip configurations is revealed in FIG. 2, mainly comprises a substrate 210, a chip 220, a soldering layer 230 and at least a foot stand 240. The substrate 210, which may be a multi-layer PCB (Printed Circuit Board), has a top surface 211 and a bottom surface 212 and has a plurality of metal pads 213 disposed in an array on the bottom surface 212. In this embodiment, the substrate 210 has a plurality of through holes 214 symmetrically arranged where the foot stands 240 are joined in the through holes 214.

The chip 220 is disposed on the top surface 211 of the substrate 210 and is electrically connected to the metal pads 213. In this embodiment, the LGA semiconductor package 200 further comprises a plurality of bumps 260 formed under the chip 220 as electrical connections between the chip 220 and the substrate 210 where the bumps 260 are electrically connected to the metal pads 213 by the internal circuit of the substrate 210, not shown in the figure.

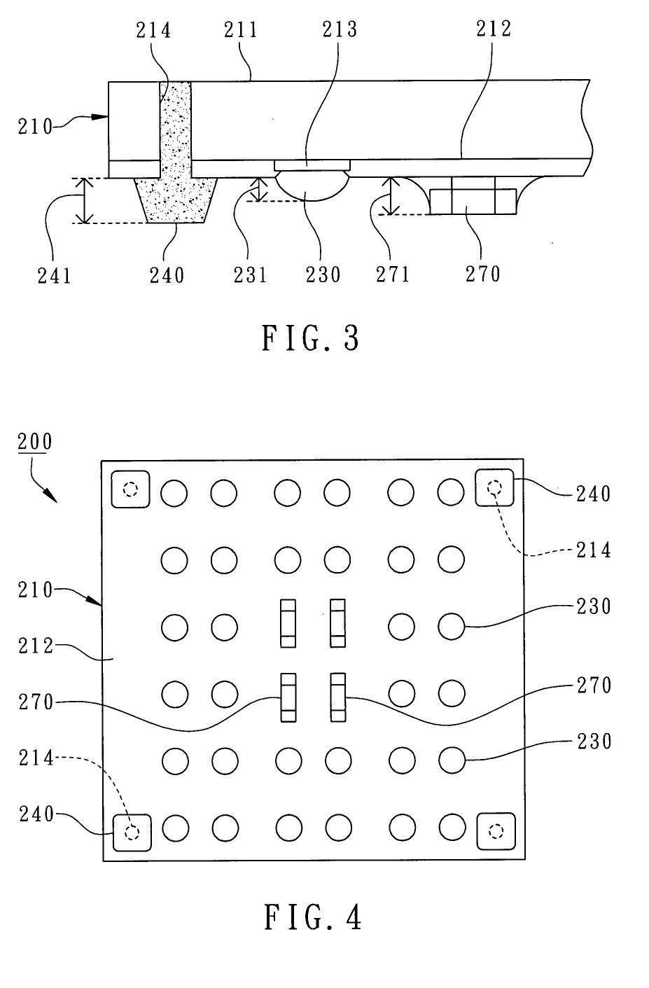

As shown in FIG. 3, the soldering layer 230 is formed on the metal pads 213 with a first thickness 231 slightly protruded from the bottom surface 212 of the substrate 210. The soldering layer 230 may be tin-lead or lead-free soldering materials that can be reflowed into small solder arcs but not solder balls by controlling the quantity of the soldering layer 230 and the dimension of metal pads 213.

The foot stand 240 is disposed under the substrate 210 with a second thickness 241 protruded from the bottom surface 212 of the substrate 210, wherein the second thickness 241 is greater than the first thickness 231. Therefore, as shown in FIG. 2 again, when the LGA semiconductor package 200 is placed on a carrying surface 20 of a carrier, such as a tabletop or cavities of trays, the metal pads 213 or the soldering layer 230 will be free from scratches or damages due to the foot stand 240. As shown in FIG. 3 and FIG. 4, the foot stand 240 comprises a plurality of supporting blocks located at the corners or at the edges of the bottom surface 240 of the substrate 210. In this embodiment, the foot stand 240 may be made of dielectric materials, such as epoxy, polyimide, resin or plastic.

As shown in FIG. 2 and FIG. 3, the LGA semiconductor package 200 further comprises a plurality of passive components 270 disposed on the bottom surface 212 of the substrate 210 with a third thickness 271 protruded from the bottom surface 212 of the substrate 210, wherein the second thickness 241 is also greater than the third thickness 271 so that the passive components 270 will not be scratched nor damaged during shipping and handling.

Moreover, the LGA semiconductor package 200 further comprises an encapsulant 250 formed on the top surface 211 of the substrate 210 to encapsulate at least a portion of the chip 220. In this embodiment, the encapsulant 250 may be formed by dispensing materials or underfill materials to encapsulate the active surface of the chip 220 and the bumps 260. Preferably, the LGA semiconductor package 200 may further have a heat sink 280 disposed on the top surface 211 of the substrate 210 to enhance heat dissipation. Accordingly, the LGA semiconductor package 200 can be surface-mounted on a circuit board by SMT processes without any specific metal-pin sockets.

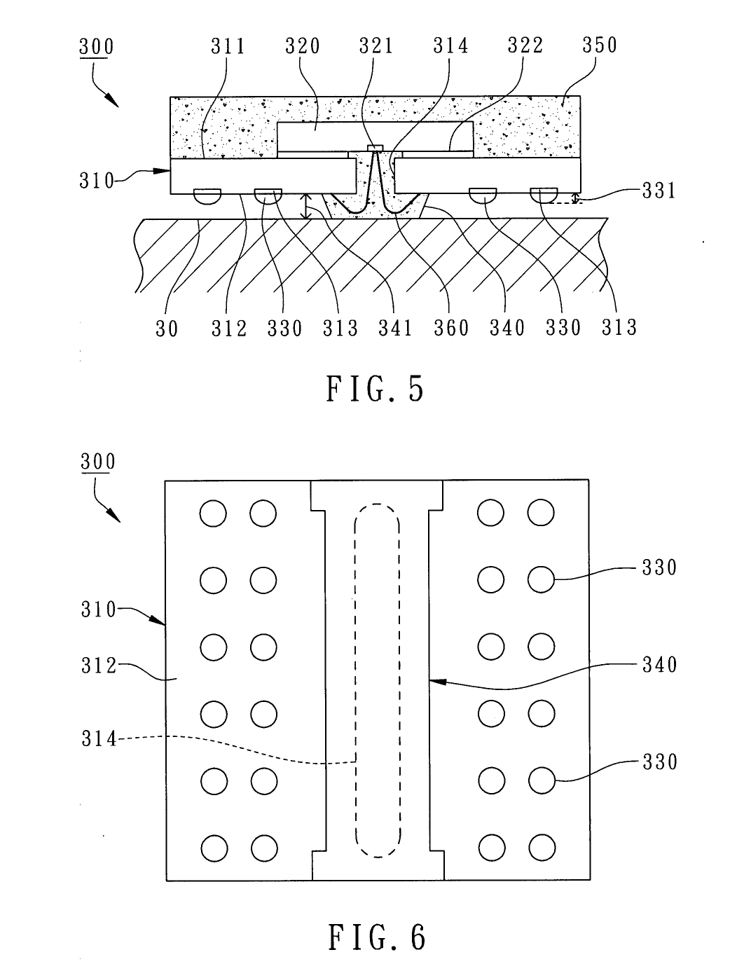

According to the second embodiment of the present invention, as shown in FIG. 5 and FIG. 6, another LGA semiconductor package 300 comprises a substrate 310, a chip 320, a soldering layer 330 and at least a foot stand 340. The substrate 310 has a top surface 311, a bottom surface 312 with a plurality of metal pads 313 disposed in an array on the bottom surface 312. In this embodiment, the substrate 310 further has a slot 314.

The chip 320 has a plurality of bonding pads 321 disposed on the active surface 322 as electrodes. The active surface 322 of the chip 320 is attached to the top surface 311 of the substrate 310 by a die-attaching adhesive with the bonding pads 321 aligned in the slot 314 of the substrate 310. The bonding pads 321 are electrically connected to the wire-bonding fingers (not shown in figure) of the substrate 310 by a plurality of bonding wires 360 passing through the slot 314. Also, the wire-bonding fingers of the substrate 310 are electrically connected to the metal pads 313 by the internal circuit of the substrate 310, not shown in the figure.

The soldering layer 330 is disposed on the metal pads 313 with a first thickness 331 slightly protruded from the bottom surface 312 of the substrate 310. The foot stand 340 is disposed under the substrate 310 with a second thickness 341 protruded from the bottom surface 312 of the substrate 310, wherein the second thickness 341 is greater than the first thickness 331. In this embodiment, the first thickness 331 of the soldering layer 330 is approximately between 80 μm and 120 μm and the second thickness 341 of the foot stand 340 is approximately between 160 μm and 200 μm. As shown in FIG. 5, the LGA semiconductor package 300 may be placed on a carrying surface 30 without contacting the soldering layer 330 because the second thickness 341 is greater than the first thickness 331. Therefore, the soldering layer 330 will not be scratched nor damaged during shipping and handling. In this embodiment, the foot stand 340 is located at the center of the bottom surface 312 of the substrate 310 and is in a strip with a shape of “I” or other shapes, as shown in FIG. 6.

The LGA semiconductor package 300 further comprises an encapsulant 350 formed on the top surface 311 of the substrate 310 to encapsulate at least a portion of the chip 320. In this embodiment, the encapsulant 350 is an epoxy molding compound (EMC) can be formed by molding to completely encapsulate the chip 320. Preferably, the foot stand 340 is integrated with the encapsulant 350 via the slot 314 to reduce the cost of disposing the foot stand 340.

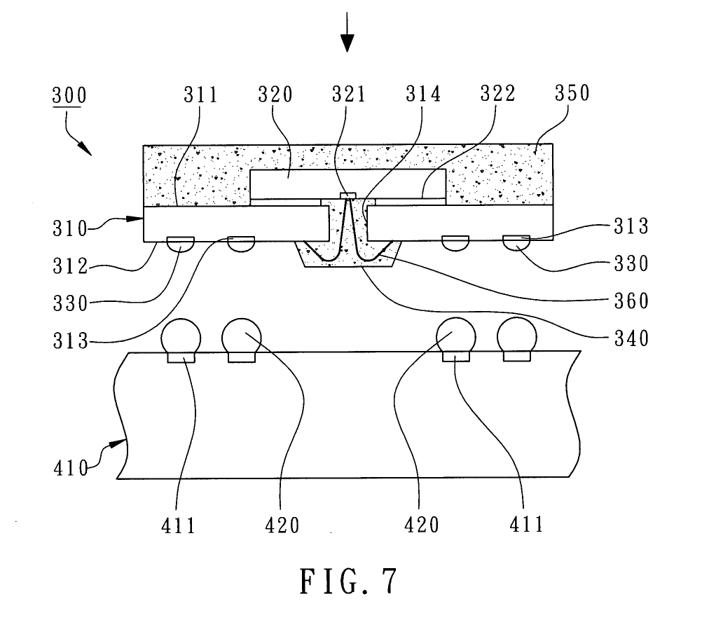

A plurality of solder balls 420 or solder paste are pre-applied on a plurality of ball pads 411 on the PCB 410 for SMT. The total height including the diameter of the solder balls 420 and the first thickness 331 of the soldering layer 330 after reflow is greater than the second thickness 341 of the foot stand 340, therefore, the soldering layer 330 will not be scratched nor damaged. As shown in FIG. 7, the LGA semiconductor package 300 is designed to be surface-mounted to a PCB 410 by SMT processes without any specific sockets, therefore, the manufacturing cost of PCB with the LGA semiconductor packages 300 implemented can be greatly reduced. Moreover, the implementations of LGA semiconductor package 300 can be increased such as memory modules where no conventional LGA semiconductor package is ever implemented.

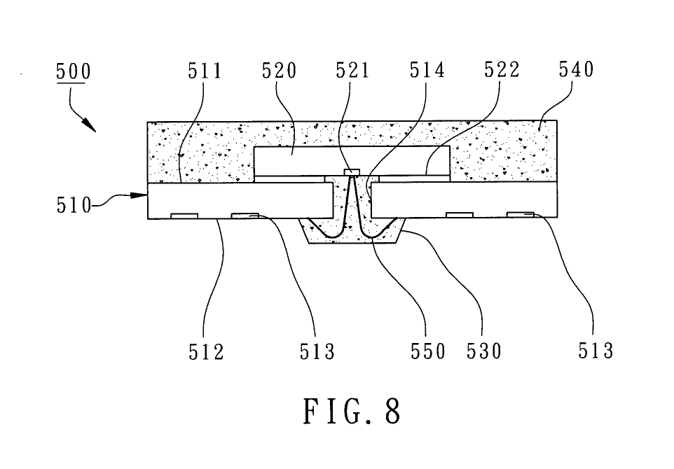

According to the third embodiment of the present invention, as shown in FIG. 8, another LGA semiconductor package 500 mainly comprises a substrate 510, a chip 520, and a foot stand 530. The substrate 510 has a top surface 511 and a bottom surface 512 with a plurality of metal pads 513 disposed in an array. In this embodiment, the substrate 510 further has a slot 514 to accommodate the foot stand 530.

The chip 520 has a plurality of bonding pads 521 formed on the active surface 522. When the active surface 522 of the chip 520 is attached to the top surface 511 of the substrate 510, the bonding pads 521 is aligned within the slot 514. The bonding pads 521 are electrically connected with the substrate 510 via a plurality of bonding wires 550 passing through the slot 514. The foot stand 530 under the substrate 510 protrudes from the bottom surface 512 so as to protect the metal pads 513 from scratches and damages. Besides, the foot stand 530 may encapsulate the bonding wires 550.

Moreover, a soldering layer (not shown in figures) such as Ni—Au layer, is disposed on the metal pads 513 with a thickness not greater than the protruded height of the foot stand 530, so that the LGA semiconductor package 500 can be horizontally placed on a surface during shipping and handling before SMT processes. In this embodiment, the LGA semiconductor package 500 further includes an encapsulant 540 formed on the top surface 511 of the substrate 510 to encapsulate the chip 520.

According to the present embodiment, when the LGA semiconductor package 500 is compared with a conventional BGA (Ball Grid Array) package, the solder ball placement step and the infrared reflowing step can be eliminated, therefore, the thermal stresses caused by the conventional reflowing processes can substantially be avoided. Moreover, when the LGA semiconductor package 500 is surface-mounted on a PCB, the metal pads 513 are electrically connected to pre-mounted solder balls or pre-applied solder paste on the PCB. Therefore, the cracks at the interfaces between the metal pads 513 and the solder balls caused by metal diffusion and gold embrittleness are also eliminate so that there is no reliability issues of solder joints.

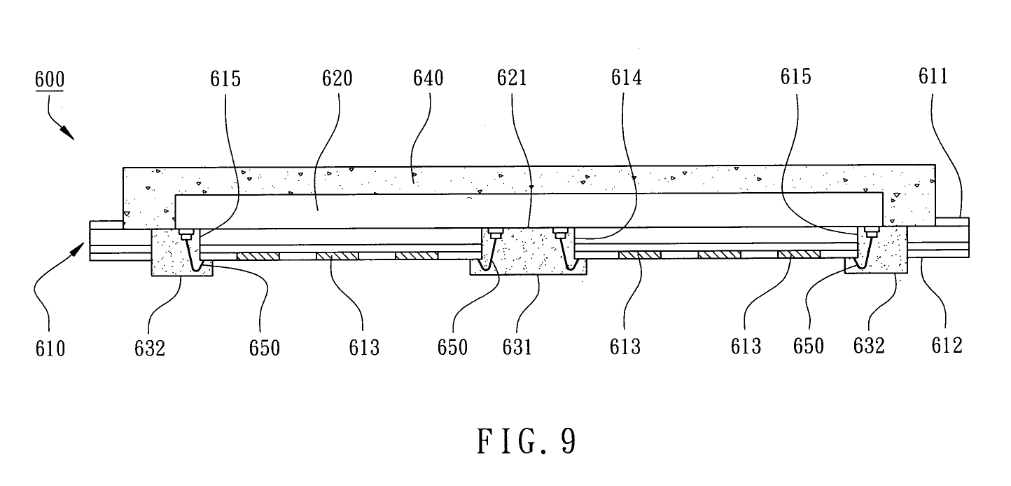

According to the fourth embodiment of the present invention, the foot stands may have various shapes and quantity. Another LGA semiconductor package 600, as shown in FIG. 9, mainly comprises a substrate 610, a chip 620 and a plurality of foot stands 631 and 632. The substrate 610 has a top surface 611, a bottom surface 612 and a plurality of metal pads 613 disposed in an array on the bottom surface 612. In this embodiment, the substrate 610 further has a plurality of mounting holes 614 and 615 to install the foot stands 631 and 632.

The surface 621 of the chip 620 with bonding pads is attached to the top surface 611 of the substrate 610 where the chip 620 is electrically connected to the substrate 610 via a plurality of bonding wires 650 passing through the mounting holes 614 and 615. When disposed in the mounting holes 614 and 615 under the substrate 610, the foot stands 631 and 632 are protruded from the bottom surface 612 of the substrate 610 to protect the metal pads 613 from scratches or damages. The foot stand 631 disposed at the center of the substrate 610 is defined as the central foot stand 631 and the foot stands 632 disposed at the peripheries of the substrate 610 are defined as the peripheral foot stands 632, moreover, the metal pads 613 are disposed between the central foot stand 631 and the peripheral foot stands 632 to enhance scratching protection of the metal pads 613. Besides, the central foot stand 631 and the peripheral foot stands 632 further encapsulate the bonding wires 650 located at the center and at the peripheries of the substrate 610.

Accordingly, the LGA semiconductor package 600 can be horizontally placed on a surface during shipping and handling without scratching nor damaging the metal pads 613. Furthermore, the LGA semiconductor package 600 can be implemented by SMT or pin sockets. In this embodiment, the LGA semiconductor package 600 further comprises an encapsulant 640 formed on the top surface 611 of the substrate 610 to encapsulate the chip 620.

While the present invention has been particularly illustrated and described in details with respect to the preferred embodiments thereof, it will be clearly understood by those skilled in the art that various changes in forms and in details may be made without departing from the spirit and scope of the present invention.

What is claimed is:

1. An LGA semiconductor package comprising:
a substrate having a top surface, a bottom surface and a plurality of metal pads, disposed in an array on the bottom surface;
a chip disposed on the top surface of the substrate and electrically connected to the metal pads;
a soldering layer disposed on the metal pads with a first thickness slightly protruded from the bottom surface; and
a foot stand disposed under the substrate with a second thickness protruded from the bottom surface, wherein the second thickness is greater than the first thickness.

2. The LGA semiconductor package of claim 1, further comprising an encapsulant formed on the top surface of the substrate to encapsulate at least a portion of the chip.

3. The LGA semiconductor package of claim 2, wherein the foot stand is integrally joined with the encapsulant.

4. The LGA semiconductor package of claim 3, wherein the substrate has a slot where the foot stand is formed in the slot and is part of the encapsulant.

5. The LGA semiconductor package of claim 4, further comprising a plurality of bonding wires passing through the slot and being encapsulated by the foot stand to electrically connect the chip with the substrate.

6. The LGA semiconductor package of claim 1, wherein the substrate has a plurality of through holes symmetrically disposed where the foot stand is placed and joined in the through holes.

7. The LGA semiconductor package of claim 1, further comprising a plurality of bumps to electrically connect the chip with the substrate.

8. The LGA semiconductor package of claim 1, wherein the foot stand is composed of a plurality of supporting blocks located at the corners or at the edges of the bottom surface of the substrate.

9. The LGA semiconductor package of claim 1, wherein the foot stand is in a shape of “I” located at the center of the bottom surface of the substrate.

10. The LGA semiconductor package of claim 1, wherein the foot stand is made of dielectric materials.

11. The LGA semiconductor package of claim 1, further comprising a plurality of passive components disposed on the bottom surface of the substrate where each passive component has a third thickness protruded from the bottom surface of the substrate, wherein the second thickness is greater than the third thickness.

12. The LGA semiconductor package of claim 1, further comprising a heat sink disposed on the top surface of the substrate.

13. An LGA semiconductor package comprising:
a substrate having a top surface, a bottom surface and a plurality of metal pads disposed in an array on the bottom surface;
a chip disposed on the top surface of the substrate and electrically connected to the metal pads; and
at least a foot stand disposed under the substrate with a thickness protruded from the bottom surface of the substrate.

14. The LGA semiconductor package of claim 13, further comprising an encapsulant formed on the top surface of the substrate to encapsulate at least a portion of the chip.

15. The LGA semiconductor package of claim 14, wherein the foot stand is integrally joined with the encapsulant.

16. The LGA semiconductor package of claim 15, wherein the substrate has a slot where the foot stand is formed in the slot and is part of the encapsulant.

17. The LGA semiconductor package of claim 16, further comprising a plurality of bonding wires passing through the slot and encapsulated by the foot stand to electrically connect the chip with the substrate.

18. The LGA semiconductor package of claim 13, wherein the foot stand is a dielectric strip disposed at the center of the bottom surface of the substrate.

19. The LGA semiconductor package of claim 13, wherein the foot stand is a central foot stand disposed at the center of the substrate protruded from the bottom surface, further comprising a plurality of peripheral foot stands disposed at the peripheries of the substrate protruded from the bottom surface, wherein the metal pads are located between the central foot stand and the peripheral foot stands.

20. The LGA semiconductor package of claim 19, wherein the substrate has a plurality of mounting holes to dispose the central foot stand and the peripheral foot stands, further comprising a plurality of bonding wires passing through the mounting holes, wherein the central foot stand and the peripheral foot stands encapsulate the bonding wires.
